(19) United States
(12) Patent Application Publication
(10) Pub. No.: US 2016/0268378 A1
(43) Pub. Date: Sep. 15, 2016

(54) INTEGRATED STRAINED FIN AND RELAXED FIN

(71) Applicant: GLOBALFOUNDRIES Inc., Grand Cayman (KY)

(72) Inventors: Pouya Hashemi, White Plains, NY (US); Ali Khakifirooz, Los Altos, CA (US); Alexander Reznicek, Troy, NY (US); Dominic J. Schepis, Wappingers Falls, NY (US)

(21) Appl. No.: 14/645,477

(22) Filed: Mar. 12, 2015

(51) Int. Cl. H01L 29/10; H01L 29/16; H01L 29/66; H01L 29/36; H01L 27/092; H01L 21/8234

(52) U.S. Cl. CPC H01L 29/1054; H01L 27/0924; H01L 21/823431; H01L 21/823412; H01L 29/6653; H01L 29/36; H01L 29/16

(57) ABSTRACT

A relaxed fin and a strained fin are formed upon a semiconductor substrate. The strained fin is more highly strained relative to relaxed fin. In a particular example, the relaxed fin may be SiGe (e.g., between 20% atomic Ge concentration and 40% atomic Ge concentration, etc.) and strained fin may be SiGe (e.g., between 50% atomic Ge concentration and 80% atomic Ge concentration, etc.). The strained fin may be located in a pFET region and the relaxed fin may be located in an nFET region of a semiconductor device. As such, mobility benefits may be achieved with the strained fin in the pFET region whilst mobility liabilities may be limited with the relaxed fin in nFET region. The height of the strained fin is greater relative to a critical thickness that which growth defects occur in an epitaxially formed Si blanket layer or in an epitaxially formed Ge blanket layer.

### FIELD

Embodiments of invention generally relate to semiconductor devices, design structures for designing a semiconductor device, and semiconductor device fabrication methods. More particularly, embodiments relate to semiconductor structures with an integrated strained fin and relaxed fin.

### BACKGROUND

The term FinFET generally refers to a nonplanar, double-gate transistor. Integrated circuits that include FinFETs may be fabricated on a bulk silicon substrate or, more commonly, on a silicon-on-insulator (SOI) wafer that includes an active SOI layer of a single crystal semiconductor, such as silicon, a semiconductor substrate, and a buried insulator layer, e.g., a buried oxide layer that separates and electrically isolates the semiconductor substrate from the SOI layer. Each FinFET generally includes a narrow vertical fin body of single crystal semiconductor material with vertically-projecting sidewalls. A gate contact or electrode intersects a channel region of the fin body and is isolated electrically from the fin body by a thin gate dielectric layer. At opposite ends of the fin body are heavily-doped source/drain regions.

Conventional methods of forming the fin body utilize subtractive techniques in which a uniformly thick fin layer, approximately 20 nm or higher, is patterned by masking and etching with a process like reactive ion etching (RIE) to form the fin bodies.

As technology node sizes shrink, it may be beneficial to utilize strained fin bodies. A strained fin body includes distorted crystal lattices, relative to silicon, which generally improves electron and hole mobility though the strained fin body. High strains are exemplarily observed within an epitaxially grown SiGe (80% Ge) layer. However, such highly strained materials may not be formed to sufficient thicknesses to serve as a fin layer. For example, the SiGe (80% Ge) layer may be grown to a critical thickness, approximately 10 nm, wherein further growth beyond the critical thickness results in lattice relaxation and the formation of other material defects.

### SUMMARY

In a first embodiment of the present invention, a semiconductor device fabrication method includes forming a first oversized fin upon a semiconductor substrate within a first region of the semiconductor device, forming a second oversized fin upon the semiconductor substrate within a second region of the semiconductor device, masking the first oversized fin, forming a relaxed fin from the second oversized fin, masking the relaxed fin and exposing the first oversized fin, and forming a strained fin from the first oversized fin.

In another embodiment of the present invention, a semiconductor device includes a semiconductor substrate, a relaxed fin upon the semiconductor substrate, and a strained fin upon the semiconductor substrate. The relaxed fin includes a relaxed material of increased crystalline lattice distortion relative to silicon. The strained fin including a strained material of increased crystalline lattice distortion relative to the relaxed material.

In yet another embodiment, the semiconductor device is included in a design structure embodied in a machine readable storage medium for designing, manufacturing, or testing an integrated circuit.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1-FIG. 12 depicts cross section views of a semiconductor structure at an intermediate stage of semiconductor device fabrication, in accordance with various embodiments of the present invention.

FIG. 13 depicts an exemplary semiconductor device fabrication process flow, in accordance with various embodiments of the present invention.

FIG. 14 depicts a flow diagram of a design process used in semiconductor design, manufacture, and/or test, in accordance with various embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments relate to semiconductor structures with an integrated strained fin and relaxed fin. Fins are formed from a relaxed fin layer. A strained fin formed by condensing a relaxed fin. The relaxed fin may be included within an nFET region of a semiconductor device and the strained fin may be included with a pFET region of the semiconductor device.

Referring now to the FIGs., exemplary process steps of forming a structure 10 in accordance with embodiments of the present invention are shown, and will now be described in greater detail below. It should be noted that some of the figures depict a cross section view of structure 10. Furthermore, it should be noted that while this description may refer to some components of the structure 10 in the singular tense, more than one component may be depicted throughout the figures and like components are labeled with like numerals. The specific number of components depicted in the figures and the cross section orientation was chosen for illustrative purposes only.

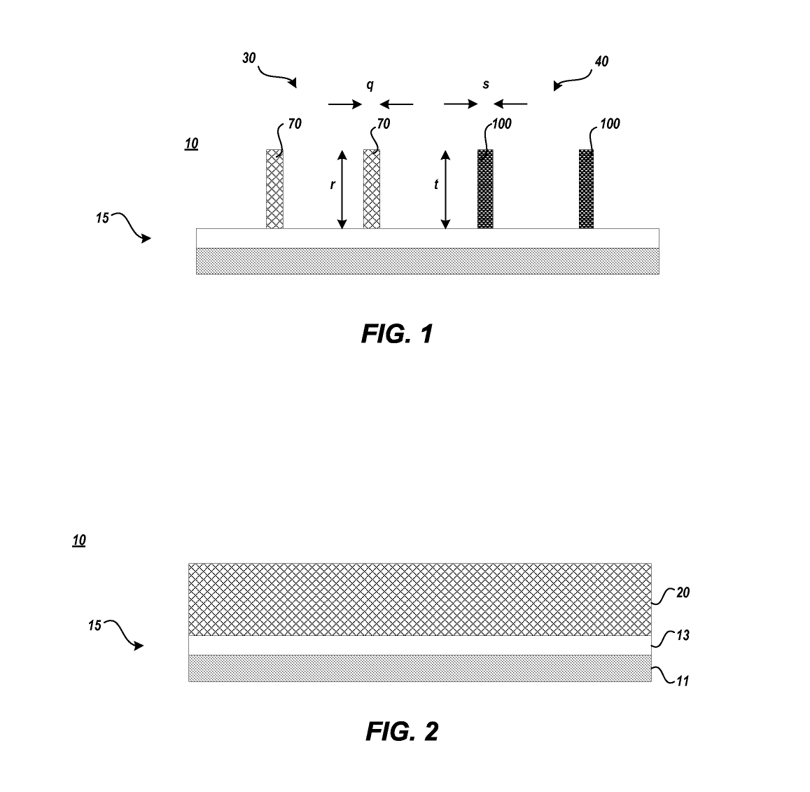

FIG. 1 depicts a cross section view of semiconductor structure 10 at an intermediate stage of semiconductor device fabrication. Semiconductor structure 10 includes a substrate 15. Structure 10 also includes relaxed fins 70 and strained fins 100. Relaxed fins 70 have a width “q”. Stained fins 100 have a width “s”. In embodiments, the width “s” of strained fins 100 and the width “q” of relaxed fins 70 may be approximately 3 nm-12 nm, with a preferred width of 8 nm. Relaxed fins 70 have a height “r”. Stained fins 100 have a height “t”. In embodiments, the height “t” of strained fins 100 and the height “r” of relaxed fins 70 may be approximately 20 nm-100 nm, with a preferred height of 40 nm to 60 nm. Strained fin 100 is a material of increased strained crystalline lattice distortion relative to relaxed fin 70. Relaxed fin 70 is a material having a relaxed crystalline lattice. In other words, strained fin 100 is a material with a lattice constant larger than that of relaxed fin 70. In a particular example, strained fin 100 is compressively strained relative to relaxed fin 70. In a particular example, relaxed fin 70 may be SiGe (with 20% atomic Ge, 25% atomic Ge, etc.) and strained fin 100 may be SiGe (with 50% atomic Ge, 75% atomic Ge, 80% atomic Ge, etc.). In other words, the Ge concentration of strained fin 100 is greater than the Ge concentration of relaxed fin 70, whilst the lattice constant of strained fin 100 is equivalent to the lattice constant of relaxed fin 70.

Structure 10 may also include an nFET region 30 and pFET region 40. One or more relaxed fins 70 may be included in nFET region 30 and one or more strained fins 100 may be included in pFET region 40. In this implementation, mobility benefits may be achieved by the strained fin 100 in pFET region 40 whilst mobility liabilities may be limited by the relaxed fin 70 in nFET region 30. Further, subsequent device integration may be more efficiently achieved due to relaxed fin 70 and strained fin 100 being a similar material (e.g., SiGe, etc.). Further, the height the height “t” of strained fins 100 and the height “r” of relaxed fins 70 is generally greater relative to the critical thickness of epitaxially grown SiGe (80% atomic Ge).

FIG. 2 depicts a cross section view of semiconductor structures 10 at an intermediate stage of semiconductor device fabrication, in accordance with various embodiments of the present invention. At the present stage of fabrication, fin layer 20 is formed upon semiconductor structure 10. As shown in FIG. 2, the substrate 15 may be a layered substrate and include base substrate 11 and a buried dielectric layer 13 formed on top of the base substrate. The fin layer 20 is formed upon of the buried dielectric layer 13. The buried dielectric layer 13 may electrically isolate the fin layer 20 from the base substrate. A plurality of fins 12 may be etched from the fin layer 20.

Fin layer 20 is generally a thermally mixed strained silicon (TMSGOI) material formed upon substrate 15. Layer 20 may be formed by thermal mixing, by wafer bonding, etc. Fin layer 20 is a material having a relaxed crystalline lattice. Fin layer 20 is generally a blanket layer in which fins may be formed therefrom. As such, fin layer 20 is formed to a thickness greater than the height the height “t” of strained fins 100 and the height “r” of relaxed fins 70. For example fin layer 20 is typically formed to a thickness of 25 nm-120 nm.

Substrate 15 may be a bulk substrate or a layered semiconductor substrate such as Si/SiGe substrate, a silicon-on-insulator (SOI) substrate, a SiGe-on-insulator (SGOI) substrate, etc. Substrate 15 may further be a bulk semiconductor substrate such as an undoped Si substrate, n-doped Si substrate, p-doped Si substrate, single crystal Si substrate, etc. When substrate 15 is a layered substrate, the base substrate 11 may be made from any of several known semiconductor materials such as, for example, Si, Ge, SiGe, SiC, SiGeC, or other similar semiconductor materials. Non-limiting examples of compound semiconductor materials include GaAs, InAs, InP, etc. Typically the base substrate may be about, but is not limited to, several hundred microns thick. For example, the base substrate may have a thickness ranging from 0.5 mm to about 1.5 mm.

The buried dielectric layer 13 may include any of several dielectric materials, for example, oxides, nitrides and oxynitrides of silicon. The buried dielectric layer may also include oxides, nitrides and oxynitrides of elements other than silicon. In addition, the buried dielectric layer 13 may include crystalline or non-crystalline dielectric material. Moreover, the buried dielectric layer may be formed using any of several known methods, for example, thermal or plasma oxidation or nitridation methods, chemical vapor deposition methods, and physical vapor deposition methods. The buried dielectric layer 13 may have a thickness ranging from about 5 nm to about 200 nm. In one embodiment, the buried dielectric layer may have a thickness ranging from about 120 nm to about 180 nm.

Fin layer 20 may be formed by TMSGOI fabrication techniques where a host layer (e.g., silicon, etc.) is formed upon buried dielectric layer 13. Note, the host layer is not shown in FIG. 2. A SiGe (15% atomic Ge-25% atomic Ge) layer (not shown) may be epitaxially grown from the host dielectric layer. The SiGe layer is pseudomorphic with respect to the host layer and is therefore compressively strained. A high temperature oxidation/anneal process causes the Ge to be rejected from the growing oxide and diffuse (i.e. mixed, etc.) into the host layer below. The resulting fin layer 20 is relaxed or partially relaxed and may have a similar crystal orientation as the base substrate 11.

Generally, expitaxial growth, grown, deposition, formation, etc. means the growth of a semiconductor material on a deposition or seed surface of a semiconductor material, in which the semiconductor material being grown has the same crystalline characteristics as the semiconductor material of the deposition surface. In an epitaxial deposition process, the chemical reactants provided by the source gasses are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a <100> crystal surface will take on a <100> orientation. In some embodiments, epitaxial growth and/or deposition processes are selective to forming on semiconductor surface, and do not deposit material on dielectric surfaces, such as silicon dioxide or silicon nitride surfaces.

Examples of various epitaxial growth process apparatuses that are suitable for use in forming epitaxial semiconductor material of the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition process for forming the carbon doped epitaxial semiconductor material typically ranges from 550° C. to 900° C. Although higher temperature typically results in faster deposition, the faster deposition may result in crystal defects, film cracking, etc.

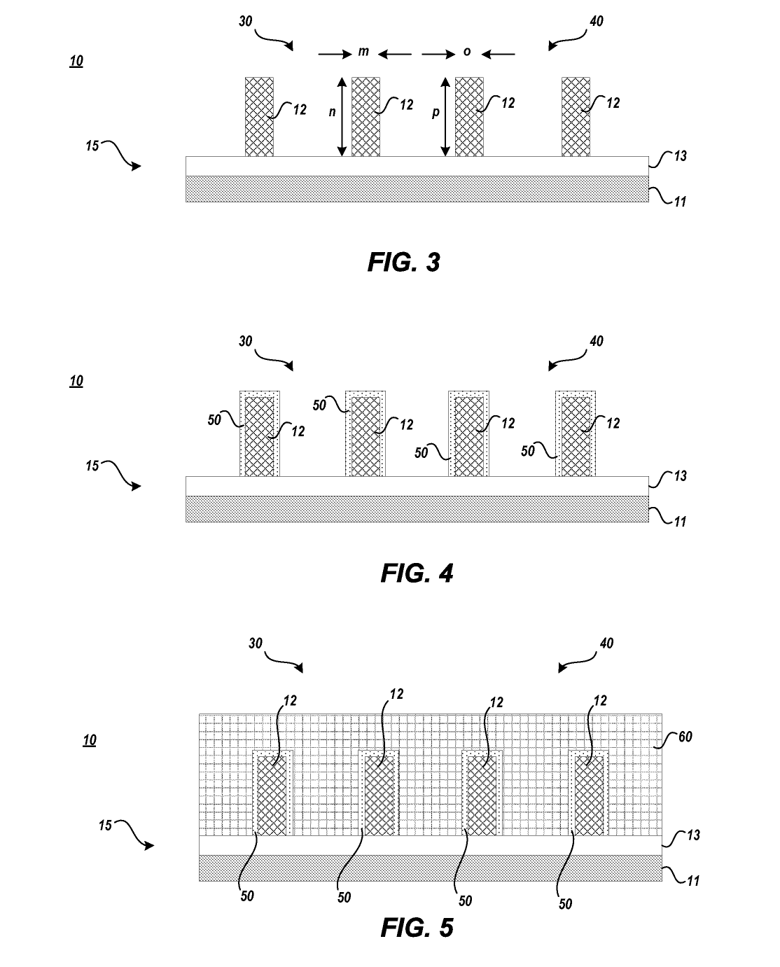

FIG. 3 depicts a cross section view of semiconductor structures 10 at an intermediate stage of semiconductor device fabrication, in accordance with various embodiments of the present invention. At the present stage of fabrication, relaxed fins 12 are formed from fin layer 20 upon semiconductor structure 10. Relaxed fins 12 may be formed by selectively removing portions of fin layer 20. In such subtractive formation processes, a mask layer (not shown) may be formed upon fin layer 20. The mask layer may be patterned. An exemplary patterned mask layer may be a hard mask that includes masking features.

The patterned mask can be formed using process steps such as, without limitation: material deposition or formation; photolithography; imaging; etching; and cleaning. For instance, a soft mask or a hard mask can be formed overlying the fin layer 20 to serve as an etch mask. Thereafter, the unprotected portions of the fin layer 20 can be etched using an appropriate etchant chemistry. The etching step may selectively etches the portions of fin layer 20 material. This etching step results in one or more fins 12 being formed from fin layer 20. As fin layer 20 is relaxed or partially relaxed, fins 12 are also relaxed or partially relaxed.

The etch process preferably employs an etchant that selectively etches portions of layer 20 while leaving substrate 15 intact or substantially intact. In embodiments, buried dielectric layer 13 may serve as an etch stop layer. Although some wet or plasma etchant chemistries may be suitable for use during the formation of fins 12, dry etchants that selectively etches fin layer 20 may also be utilized. The selective etching of fin layer 20 forms fins 12. In some embodiments, the portions of the mask layer may be retained upon the fins 12 (not shown) and may serve as fin caps that reside on fins 12. Generally, fins 12 may be formed upon a semiconductor structure 10 by other known processes or techniques without deviating from the spirit of those embodiments herein claimed.

Relaxed fin 12 within nFET region 30 has a width “m” and height “n.” Relaxed fin 12 within pFET region 40 has a width “o” and height “p.” In embodiments, the width “m” of relaxed fins 12 and the width “o” of relaxed fins 12 may be approximately 5 nm-20 nm, with a preferred width of 8 nm. In other words, the width of relaxed fin 12 is greater than the width “q” of relaxed fin 70 or than the width “s” of strained fin 100. Further, the height “r” of relaxed fins 12 and the height “t” of relaxed fins 12 may be approximately 22 nm-60 nm, with a preferred height of 50 nm. In other words, the height of relaxed fin 12 is greater than the height “r” of relaxed fin 70 or than the height “t” of strained fin 100. The height and width of relaxed fins 12 is greater than the respective height and width of relaxed fin 12 and strained fin 100, as some of the fin 12 material may be sacrificed during the fabrication of strained fin 100 and relaxed fin 70, as is further described herein.

FIG. 3 depicts a cross section view of semiconductor structures 10 at an intermediate stage of semiconductor device fabrication, in accordance with various embodiments of the present invention. At the present stage of fabrication, sacrificial spacer 50 is formed upon fin 12.

The sacrificial spacer 50 is formed adjacent to and upon the sidewalls of the fins 12. Spacers 50 can be formed in a conventional manner using well known process techniques (e.g. Rapid Thermal Oxidation, Rapid Thermal Nitridization, etc.). Spacers 50 may be formed to protect fins 12 during subsequent structure 10 fabrication stages. In this regard, spacers 50 may be formed by depositing a layer of spacer material (e.g., silicon oxide, silicon nitride, etc.) over exposed surfaces (i.e., sidewalls of fins 12, etc.) of semiconductor structure 10, followed by etching of the deposited spacer material that selectively removes undesired spacer material while substrate 15 remains substantially intact. This results in the formation of spacers 50 that terminate at buried dielectric layer 13. Spacers 50 are preferably formed such that a gap remains between adjacent and facing spacers 50. Each gap terminates at an exposed surface buried dielectric layer 13, where this exposed surface resides between two adjacent spacers 50. Generally, sacrificial spacer 50 may be formed upon a semiconductor structure 10 by other known processes or techniques without deviating from the spirit of those embodiments herein claimed.

FIG. 5 depicts a cross section view of semiconductor structures 10 at an intermediate stage of semiconductor device fabrication, in accordance with various embodiments of the present invention. At the present stage of fabrication, dielectric layer 60 is formed upon structure 10. Dielectric layer 60 may be formed utilizing a conventional deposition process including, for example, chemical vapor deposition, plasma enhanced chemical vapor deposition or chemical solution deposition. Dielectric layer 60 is formed to a thickness greater than height of fins 12. Dielectric layer may be formed to protect nFET region 30 and/or pFET region 40 during subsequent fabrication processes. Dielectric layer 60 may be silicon (e.g., amorphous silicon, poly silicon, etc.) or other suitable dielectric material that may be selectively removed relative to spacers 50 and buried dielectric layer 13.

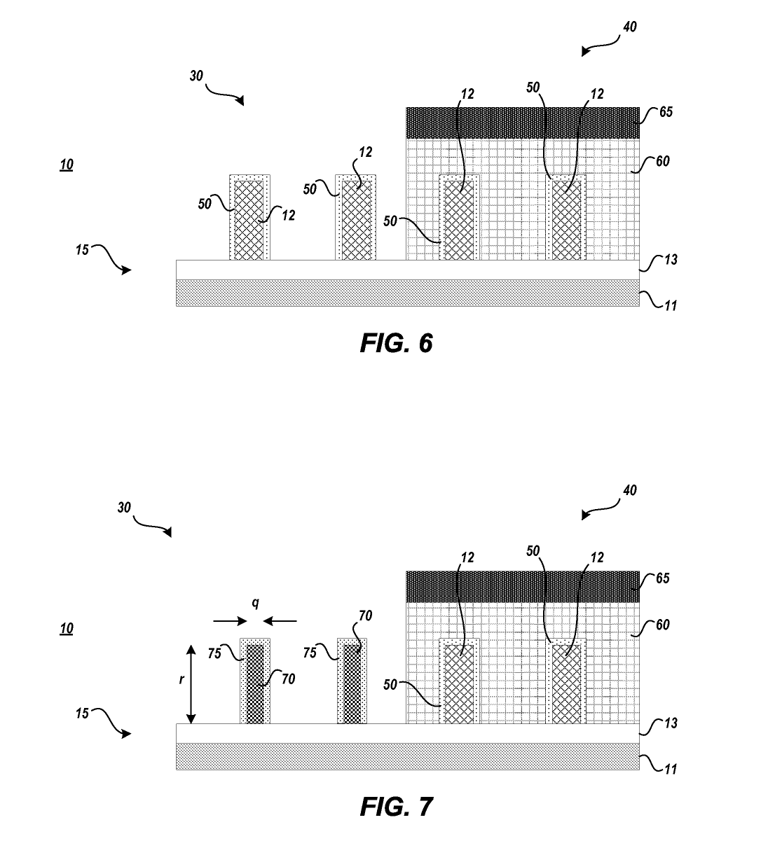

FIG. 6 depicts a cross section view of semiconductor structures 10 at an intermediate stage of semiconductor device fabrication, in accordance with various embodiments of the present invention. At the present stage of fabrication, a mask layer 65 is formed upon structure 10 and nFET region 30 is exposed.

Mask layer 65 may be formed upon dielectric layer 60. The mask layer 65 may be patterned. An exemplary patterned mask layer may be a hard mask that includes masking features. The patterned mask 65 can be formed using process steps such as, without limitation: material deposition or formation of layer 65; photolithography; imaging; etching; and cleaning. For instance, a soft mask 65 or a hard mask 65 can be formed upon dielectric layer 60 to serve as an etch mask. Thereafter, the unprotected nFET region 30 can be etched using an appropriate etchant chemistry. The etching step may selectively remove dielectric layer 60 material in nFET region 30. This etching step results in one or more nFET region 30 fins 12 and associated spacer 50 being exposed. It is understood that dielectric layer 60 and mask 65 may be formed via, e.g., deposition, sputtering, epitaxial growth, etc.

The etch process preferably employs an etchant that selectively etches portions of layer 60 while nFET region 30 fins 12 and associated spacers 50, substrate 15, etc. remain intact or substantially intact. In embodiments, the buried dielectric layer 13 may serve as an etch stop layer. Although some wet or plasma etchant chemistries may be suitable for use to expose nFET region 30 fins 12 and associated spacers 50, dry etchants that selectively etches layer 60 may also be utilized. Generally, nFET regions 30 may be exposed upon semiconductor structure 10 by other known processes or techniques without deviating from the spirit of those embodiments herein claimed.

FIG. 7 depicts a cross section view of semiconductor structures 10 at an intermediate stage of semiconductor device fabrication, in accordance with various embodiments of the present invention. At the present stage of fabrication, relaxed fin 70 is formed upon structure 10 and sacrificial spacer 75 is formed upon relaxed fin 70. More particularly the relaxed fin 70 may be formed by a subtractive etch of fin 12 within nFET region 30. Subsequently, spacer 75 may be formed upon relaxed fin 70.

In a particular subtractive etching process, following the exposing of nFET region 30, a dilute hydrogen-flouride (DHF) cleaning may be performed on the exposed nFET region 30, to form relaxed fin 70 of preferred width “q” and preferred height “r.” That is, the DHF cleaning may reduce fin 12 height “n” and fin 12 width “m” to width “q” and height “r.” As dielectric layer 60 and mask 65 is protecting pFET region 40, the DHF cleaning of is not performed on the masked pFET region 40.

In another subtractive etching process, following the exposing of nFET region 30, a SC1 cleaning may be performed on the exposed nFET region 30, to form relaxed fin 70 of preferred width “q” and preferred height “r.” SC1 includes hydrogen peroxide, ammonium hydroxide, and water. The designation SC1 is shorthand notation for Standard Clean 1. The SC1 cleaning may reduce fin 12 height “n” and fin 12 width “m” to width “q” and height “r.” As dielectric layer 60 and mask 65 is protecting pFET region 40, the SC1 cleaning of is not performed on the masked pFET region 40.

Following formation of relaxed fin 70, fin spacer 75 is formed adjacent to and upon the sidewalls of the relaxed fin 70. Spacers 75 can be formed in a conventional manner using well known formation techniques (e.g. Rapid Thermal Oxidation, Rapid Thermal Nitridization, etc.). Spacers 75 may protect the fin 70 during subsequent structure 10 fabrication stages. In this regard, spacers 75 may be formed by depositing a layer of spacer material (e.g., silicon oxide, silicon nitride, etc.) over exposed surfaces (i.e., sidewalls of fins 70, etc.) of semiconductor structure 10, followed by etching of the deposited spacer material that selectively removes undesired spacer material while substrate 15 remains substantially intact. This results in the formation of spacers 75 that terminate at buried dielectric layer 13. Spacers 75 are preferably formed such that a gap remains between adjacent and facing spacers 75. Each gap terminates at an exposed surface buried dielectric layer 13, where this exposed surface resides between two adjacent spacers 75. Generally, spacer 75 may be formed upon a semiconductor structure 10 by other known processes or techniques without deviating from the spirit of those embodiments herein claimed.

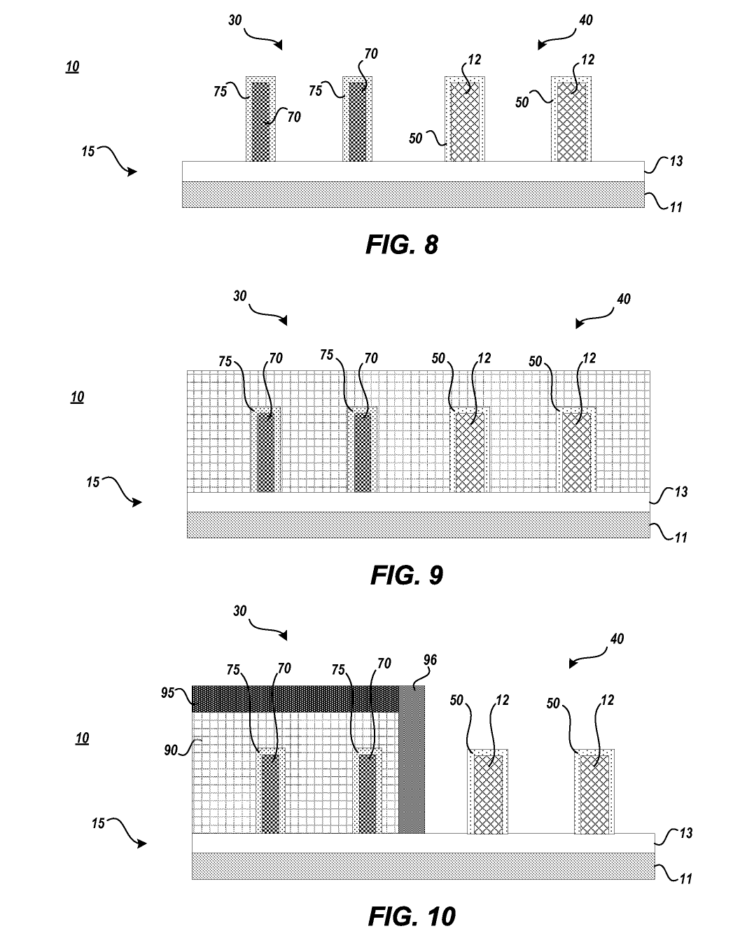

FIG. 8 depicts a cross section view of semiconductor structures 10 at an intermediate stage of semiconductor device fabrication, in accordance with various embodiments of the present invention. At the present stage of fabrication, dielectric layer 60 and mask 65 are removed to expose pFET region 40. The dielectric layer 60 and mask 65 may be removed (e.g., via conventional etching or bath techniques). The etchant may be selected to selectively remove dielectric layer 60 and mask 65 from spacer 50 within pFET region 40 and stop upon the buried dielectric layer 13.

FIG. 9 depicts a cross section view of semiconductor structures 10 at an intermediate stage of semiconductor device fabrication, in accordance with various embodiments of the present invention. At the present stage of fabrication, dielectric layer 90 is formed upon structure 10. Dielectric layer 90 may be formed utilizing a conventional deposition process including, for example, chemical vapor deposition, plasma enhanced chemical vapor deposition or chemical solution deposition. Dielectric layer 90 is formed to a thickness greater than height of relaxed fin 70 and fin 12. Dielectric layer 90 may be formed to protect nFET region 30 and/or pFET region 40 during subsequent fabrication processes. Dielectric layer 90 may be silicon (e.g., amorphous silicon, poly silicon, etc.) or other suitable dielectric material that may be selectively removed relative to spacers 50 and spacers 75 and buried dielectric layer 13.

FIG. 10 depicts a cross section view of semiconductor structures 10 at an intermediate stage of semiconductor device fabrication, in accordance with various embodiments of the present invention. At the present stage of fabrication, mask layer 95 and block spacer 96 are formed upon structure 10 and pFET region 40 is exposed.

Mask layer 95 may be formed upon dielectric layer 90. The mask layer 95 may be patterned. An exemplary patterned mask layer may be a hard mask that includes masking features. The patterned mask 95 can be formed using process steps such as, without limitation: material deposition or formation of layer 90; photolithography; imaging; etching; and cleaning. For instance, a soft mask 95 or a hard mask 95 can be formed upon dielectric layer 90 to serve as an etch mask. Thereafter, the unprotected pFET region 40 can be etched using an appropriate etchant chemistry. The etching step may selectively remove dielectric layer 90 material in pFET region 40. This etching step results in one or more pFET region 40 fins 12 and associated spacer 50 being exposed. It is understood that dielectric layer 90 and mask 95 may be formed via, e.g., deposition, sputtering, epitaxial growth, etc.

The etch process preferably employs an etchant that selectively etches portions of layer 90 while pFET region 40 fins 12 and associated spacers 50, substrate 15, etc. remain intact or substantially intact. In embodiments, the buried dielectric layer 13 may serve as an etch stop layer. Although some wet or plasma etchant chemistries may be suitable for use to expose pFET region 40 fins 12 and associated spacers 50, dry etchants that selectively etches layer 90 may also be utilized. Generally, pFET regions 40 may be exposed upon semiconductor structure 10 by other known processes or techniques without deviating from the spirit of those embodiments herein claimed.

Block spacer 96 may be formed adjacent to and upon the respective sidewalls of dielectric layer 90 and mask 95. Block spacer 96 can be formed in a conventional manner using well known process techniques (e.g. Rapid Thermal Oxidation, Rapid Thermal Nitridization, etc.). Block spacer 96 may further isolate and protect nFET region 30 during subsequent fabrication processes. In this regard, block spacer 96 may be formed by depositing a layer of spacer material (e.g., silicon oxide, silicon nitride, etc.) upon substrate 15 adjacent to and upon sidewalls of dielectric 90 and mask 95, followed by etching of the deposited spacer material that selectively removes undesired spacer material while substrate 15 remains substantially intact. Generally, spacer 96 may be formed upon a semiconductor structure 10 by other known processes or techniques without deviating from the spirit of those embodiments herein claimed.

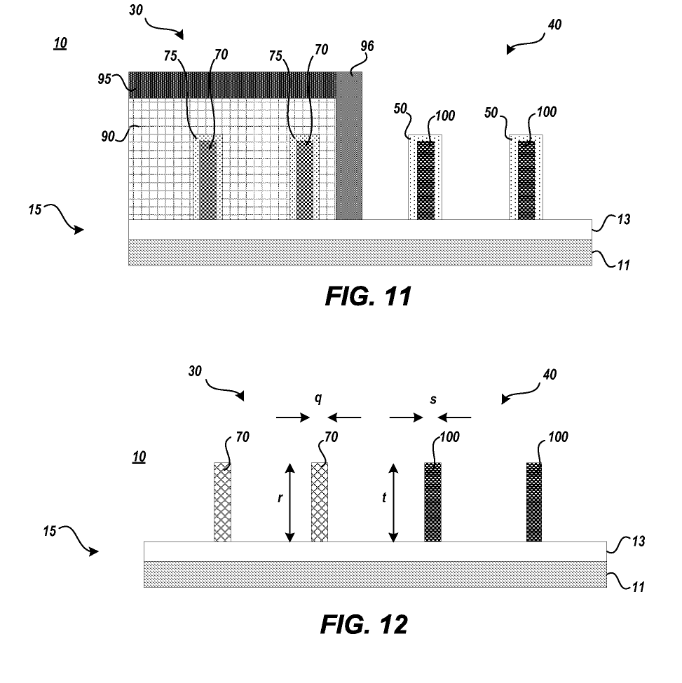

FIG. 11 depicts a cross section view of semiconductor structures 10 at an intermediate stage of semiconductor device fabrication, in accordance with various embodiments of the present invention. At the present stage of fabrication, strained fin 100 is formed upon structure 10. More specifically, strained fin 100 is formed by subjecting fin 12 in pFET region 40 to a thermal mixing or thermal condensation process to increase fin strain.

For example, the structure undergo a mixing with a thermal annealing in an oxygen containing ambient. In embodiments, the thermal annealing is performed at a temperature of about 850° C. to 1330° C., for a time period of about 10-1800 minutes. This results in the SiGe material of fin being placed in a compressive state for the pFET region 40. In another example, the structure may undergo a Ge condensation process to convert the pFET region 40 into a compressively strained SiGe region. In embodiments, the Ge condensation process can be performed by annealing oxidizing the structure so that Ge diffuses into Si in the pFET region 40, while Si is oxidized. The lattice template of the SiGe generally remains constant during the oxidation of the Si. This results in the SiGe material of fin becoming denser and being placed in a compressive state within the pFET region 40. Further, the oxidation of the Si results in the relative atomic Ge concentration of the SiGe material to increase. During the thermal mixing/condensation process, Si in the SiGe material is oxidized, and the relative size of the fin is reduced, resulting in the forming of strained fin 100 of preferred width “s” and preferred height “t.” Generally, strained fin 100 may be formed upon a semiconductor structure 10 by other known processes or techniques without deviating from the spirit of those embodiments herein claimed.

FIG. 12 depicts a cross section view of semiconductor structures 10 at an intermediate stage of semiconductor device fabrication, in accordance with various embodiments of the present invention. At the present stage of fabrication, mask 95, block spacer 96, dielectric layer 90, sacrificial spacer 75, and sacrificial spacer 50 is removed from structure 10.

For example, the mask 95, block spacer 96, and dielectric 90 may be removed from the nFET region 30 by (e.g., via conventional etching or bath techniques). One or more etchants or etch stages may be chosen to selectively remove the mask 95, block spacer 96, and dielectric 90 from spacer 50 within pFET region 40 and from spacer 75 within nFET region 30 and stop upon the buried dielectric layer 13. A subsequent etch stage may then selectively remove sacrificial spacer 75 to expose relaxed fin 75 within nFET region 30 and/or selectively remove sacrificial spacer 50 to expose strained fin 100 within pFET region 40.

In certain embodiments, a chemical and mechanical polish (CMP) process may planarize the relaxed fins 70 and strained fins 100. In other words, the height “r” of relaxed fin 70 may be similar to the height “t” of strained fins 100. The CMP process may include the deposition of a blanket layer upon substrate 15 to a thickness greater than strained fins 100 and relaxed fins 70. The CMP process may then planarize the blanket layer, the relaxed fins 70, and strained fins 100. Thereafter, the remaining blanket layer material may be removed resulting in structure 10 as shown in FIG. 12.

For clarity, structure 10 as shown in FIG. 12, may undergo further fabrication steps that may add or remove layers, materials, etc. in further front end of line, middle end of (MEOL) line, or back end of line fabrication steps to form a semiconductor device. For example, structure 10 may also include a gate formed upon substrate 15 and upon relaxed fin 70 and strained fin 100. A gate dielectric layer may be formed upon substrate 15 and upon relaxed fin 70 and strained fin 100, generally orthogonal to relaxed fin 70 and strained fin 100 utilizing a conventional deposition process including, for example, chemical vapor deposition, plasma enhanced chemical vapor deposition or chemical solution deposition. A layer of gate material may be formed upon gate dielectric, and a gate cap may be formed upon the gate material. The layers may then patterned by lithography and etched to form a gate stack. In certain embodiments, spacers may be formed on the sides of the gate stack.

The various embodiments described herein offer potential advantages. Particularly, one or more relaxed fins 70 may be included in nFET region 30 and one or more strained fins 100 may be included in pFET region 40. Mobility benefits may be achieved by the strained fin 100 in pFET region 40 whilst mobility liabilities may be limited with the relaxed fin 70 in nFET region 30. Further, subsequent device integration may be more efficiently achieved due to relaxed fin 70 and strained fin 100 being a similar material (e.g., SiGe, etc.). Further, the height the height “t” of strained fins 100 and the height “r” of relaxed fins 70 may be greater relative to the critical thickness of epitaxially grown SiGe (e.g., 80% atomic Ge). In other words, strained fins 100 of a height “t” greater than critical thickness of epitaxially grown SiGe (e.g., 80% atomic Ge) may be achieved.

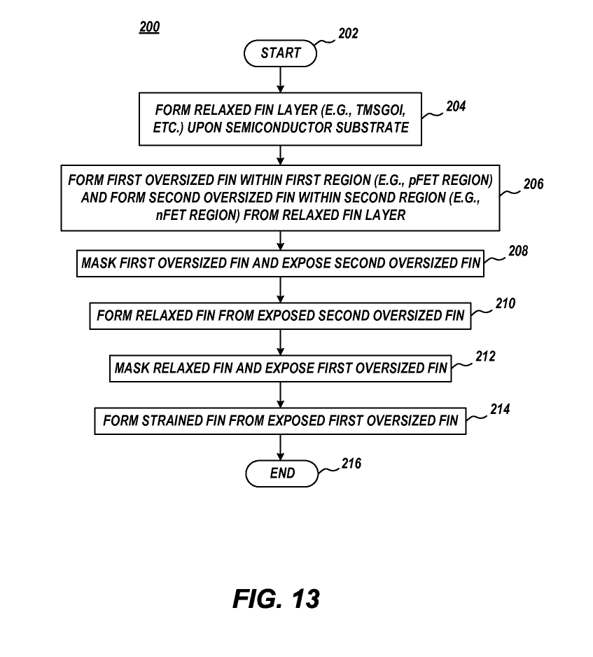

FIG. 13 depicts an exemplary method 200 for fabricating a semiconductor device, in accordance with various embodiments of the present invention. Process 200 begins at block 202 and continues by forming a relaxed fin layer 20 upon a semiconductor substrate 15 (block 204). For example, fin layer 20 may be formed by TMSGOI fabrication techniques where a host layer (e.g., silicon, etc.) is formed upon buried dielectric layer 13. More particularly, a SiGe (15% atomic Ge-25% atomic Ge) layer may be epitaxially grown from the host dielectric layer. The SiGe layer is pseudomorphic with respect to the host layer and is therefore compressively strained. A high temperature oxidation/anneal process causes the Ge to be rejected from the growing oxide and diffuse (i.e. mixed, etc.) into the host layer below.

Method 200 may continue by forming a first oversized fin in a first region and forming a second oversized fin in a second region (block 206). For example, a first relaxed fin 12 may be formed in pFET region 40 by subtractive etching of portions of fin layer 20 and a second relaxed fin 12 may be formed in nFET region 30 by subtractive etching of portions of fin layer 20. Fin 12 within nFET region 30 has a width “m” and height “n” which are relatively larger than a final relaxed fin 70 within nFET region 30. Fin 12 within pFET region 40 has a width “o” and height “p” which are relatively larger than a final strained fin 100 within pFET region 40. In embodiments, fin 12 material may be sacrificed during the fabrication of strained fin 100 and relaxed fin 70. In some implementations, a sacrificial spacer 50 may be formed upon fin(s) 12.

Method 200 may continue by masking the first oversized fin and exposing the second oversized fin (block 208). For example, a dielectric layer 60 may be formed utilizing a conventional deposition process including, e.g., chemical vapor deposition, plasma enhanced chemical vapor deposition or chemical solution deposition to a thickness greater than height of fins 12. Dielectric layer 60 may be formed to protect pFET region 40 during subsequent fabrication processes. Subsequently, a mask layer 65 is formed upon layer 60 and nFET region 30 is exposed. The mask layer 65 may be patterned using process steps such as, without limitation: material deposition or formation of layer 65; photolithography; imaging; etching; and cleaning. For example, a soft mask 65 or a hard mask 65 can be formed upon dielectric layer 60 to serve as an etch mask. Thereafter, the unprotected nFET region 30 can be etched using an appropriate etchant chemistry. The etching step may selectively remove dielectric layer 60 material in nFET region 30. This etching step results in one or more nFET region 30 fins 12 and associated spacers 50 being exposed.

Method 200 may continue by forming relaxed fin 70 from the exposed second oversized fin (block 210). The relaxed fin 70 may be formed by a subtractive etch of fin 12 within nFET region 30. Subsequently, spacer 75 may be formed upon relaxed fin 70. The etching of fin 12 may be by a DHF cleaning on the exposed nFET region 30, to form relaxed fin 70 of preferred width “q” and preferred height “r.” That is, the DHF cleaning may reduce fin 12 height “n” and fin 12 width “m” to width “q” and height “r.” In another example, a SC1 cleaning may be performed on the exposed nFET region 30, to form relaxed fin 70 of preferred width “q” and preferred height “r.” The SC1 cleaning may reduce fin 12 height “n” and fin 12 width “m” to width “q” and height “r.” As pFET region 40 is masked, etching of fin 12 within pFET region 40 does not occur. In some implementations, following formation of relaxed fin 70, sacrificial spacer 75 is formed adjacent to and upon the sidewalls of the relaxed fin 70.

Method 200 may continue my masking the relaxed fin 12 and exposing the first oversized fin (block 212). For example, dielectric layer 90 is formed upon substrate 15 by, e.g., chemical vapor deposition, plasma enhanced chemical vapor deposition or chemical solution deposition to a thickness greater than height of relaxed fin 70 and fin 12. Dielectric layer 90 may be formed to protect nFET region 30 during subsequent fabrication processes. Further, mask layer 95 may be formed upon dielectric layer 90. The mask layer 95 may be patterned using process steps such as, without limitation: material deposition or formation of layer 90; photolithography; imaging; etching; and cleaning. A soft mask 95 or a hard mask 95 can be formed upon dielectric layer 90 to serve as an etch mask. Thereafter, the unprotected pFET region 40 can be etched using an appropriate etchant chemistry. The etching step may selectively remove dielectric layer 90 material in pFET region 40. This etching step results in one or more pFET region 40 fins 12 and associated spacer 50 being exposed. Further, a block spacer 96 may be formed adjacent to and upon the respective sidewalls of dielectric layer 90 and mask 95. Block spacer 96 can be formed in a conventional manner using well known process techniques (e.g. Rapid Thermal Oxidation, Rapid Thermal Nitridization, etc.). Block spacer 96 may further isolate and protect nFET region 30 during subsequent fabrication processes.

Method 200 may continue with forming strained fin 100 from the exposed first oversized fin (block 214). Strained fin 100 is formed by subjecting fin 12 in pFET region 40 to a thermal mixing or thermal condensation process to increase fin strain. For example, fin 12 may undergo a Ge mixing with a thermal annealing in an oxygen containing ambient. This results in the SiGe material of fin 12 being placed in a compressive state for the pFET region 40 to form strained fin 100. Further, such process converts the pFET region 40 into a compressively strained region. For example, the condensation process can be performed by annealing oxidizing the structure so that Si is oxidized and the atomic Ge concentration the SiGe material increase in the pFET region 40. This results in the SiGe material of fin 12 being placed in a compressive state for the pFET region 40 to form strained fin 100. During the thermal mixing/condensation process, Si in the SiGe material is oxidized and the relative size of the fin is reduced, resulting in the forming of strained fin 100 of preferred width “s” and preferred height “t.”

In embodiments, method 200 may continue by exposing relaxed fin 70 and strained fin 100. In other words, the mask protecting relaxed fin 70 may be removed. The relaxed fin 70 and strained fin 100 may be planarized by CMP processes. For example, a blanked layer may be formed upon substrate 15 to a thickness greater than relaxed fin 70 and strained fin 100, and a CMP process may planarize the blanket layer, the relaxed fin 70, and the strained fin 100, such that the upper surface of relaxed fin 70 and the upper surface of strained fin 100 are co-planar. The blanket layer may be removed. Further subsequent semiconductor device fabrication techniques may be performed, such as forming replacement relaxed fin 70 spacers, forming replacement strained fin 100 spacers, forming a gate upon the substrate, upon the relaxed fin 70, and upon the strained fin 100, etc. Method 200 may end at block 216.

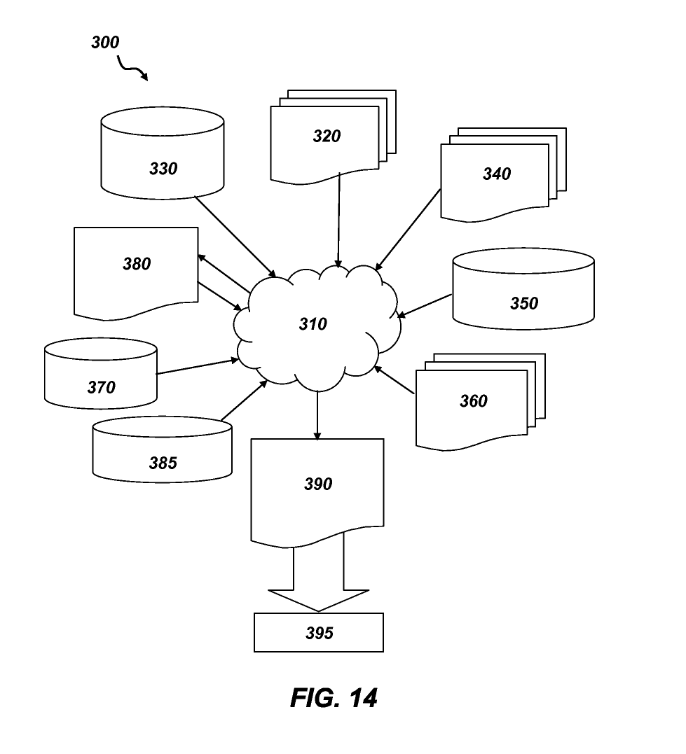

Referring now to FIG. 14, a block diagram of an exemplary design flow 300 used for example, in semiconductor integrated circuit (IC) logic design, simulation, test, layout, and/or manufacture is shown. Design flow 300 includes processes, machines and/or mechanisms for processing design structures or devices to generate logically or otherwise functionally equivalent representations of the structures and/or devices described above and shown in FIGS. 1-12.

The design structures processed and/or generated by design flow 300 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 300 may vary depending on the type of representation being designed. For example, a design flow 300 for building an application specific IC (ASIC) may differ from a design flow 300 for designing a standard component or from a design flow 300 for instantiating the design into a programmable array, for example a programmable gate array (PGA) or a field programmable gate array (FPGA) offered by Altera® Inc. or Xilinx® Inc.

FIG. 14 illustrates multiple such design structures including an input design structure 320 that is preferably processed by a design process 310. Design structure 320 may be a logical simulation design structure generated and processed by design process 310 to produce a logically equivalent functional representation of a hardware device. Design structure 320 may also or alternatively comprise data and/or program instructions that when processed by design process 310, generate a functional representation of the physical structure of a hardware device. Whether representing functional and/or structural design features, design structure 320 may be generated using electronic computer-aided design (ECAD) such as implemented by a core developer/designer.

When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device, structure, or system such as those shown in FIGS. 1-12. As such, design structure 320 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 310 preferably employs and incorporates hardware and/or software modules for synthesizing, translating, or otherwise processing a design/simulation functional equivalent of the components, circuits, devices, or structures shown FIGS. 1-12 to generate a Netlist 380 which may contain design structures such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an iterative process in which netlist 380 is resynthesized one or more times depending on design specifications and parameters for the device. As with other design structure types described herein, netlist 380 may be recorded on a machine-readable data storage medium or programmed into a programmable gate array. The storage medium may be a non-volatile storage medium such as a magnetic or optical disk drive, a programmable gate array, a compact flash, or other flash memory. Additionally, or in the alternative, the storage medium may be a system or cache memory, buffer space, or electrically or optically conductive devices in which data packets may be intermediately stored.

Design process 310 may include hardware and software modules for processing a variety of input data structure types including Netlist 380. Such data structure types may reside, for example, within library elements 330 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 340, characterization data 350, verification data 360, design rules 370, and test data files 385 which may include input test patterns, output test results, and other testing information. Design process 310 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 310 without deviating from the scope and spirit of the invention claimed herein. Design process 310 may also include modules for performing standard circuit design processes such as timing analysis, verification, design rule checking, place and route operations, etc.

Design process 310 employs and incorporates logic and physical design tools such as HDL compilers and simulation model build tools to process design structure 320 together with some or all of the depicted supporting data structures along with any additional mechanical design or data (if applicable), to generate a second design structure 390. Design structure 390 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures).

Similar to design structure 320, design structure 390 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-12. In one embodiment, design structure 390 may comprise a compiled, executable HDL simulation model that functionally simulates the devices shown in FIGS. 1-12.

Design structure 390 may also employ a data format used for the exchange of layout data of integrated circuits and/or symbolic data format (e.g. information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-12. Design structure 390 may then proceed to a stage 395 where, for example, design structure 390: proceeds to tape-out, is released to manufacturing, is released to a mask house, is sent to another design house, is sent back to the customer, etc.

It should be noted that some features of the present invention may be used in an embodiment thereof without use of other features of the present invention. As such, the foregoing description should be considered as merely illustrative of the principles, teachings, examples, and exemplary embodiments of the present invention, and not a limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as discussed above may be used in the fabrication of integrated circuit chips. The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products (such as, but not limited to, an information processing system) having a display, a keyboard, or other input device, and a central processor.

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

1.-11. (canceled)

12. A semiconductor device comprising:
a semiconductor substrate comprising a buried dielectric layer on a base substrate, wherein the buried dielectric layer is composed of an oxide, nitride, or oxynitride;
a relaxed fin directly upon the buried dielectric layer, the relaxed fin comprising a relaxed material having a relaxed crystalline lattice, and;
a strained fin directly upon the buried dielectric layer, the strained fin comprising a strained material of increased crystalline lattice strain relative to the relaxed material,
wherein the relaxed material is SiGe having a first atomic Ge concentration, and the strained material is SiGe having a second atomic Ge concentration greater than the first Ge concentration.

13. The semiconductor device of claim 12, wherein the first atomic Ge concentration is between 20% and 40%.

14. The semiconductor device of claim 12, wherein the second atomic Ge concentration is at least 50%.

15. The semiconductor device of claim 12, wherein the strained fin is located within a first semiconductor device region and the relaxed fin is located within a second semiconductor device region, the first semiconductor device region being an opposite polarity relative to the second semiconductor device region.

16. The semiconductor device of claim 15, wherein the first region of the semiconductor device is a pFET region and the second region of the semiconductor device is a nFET region.

17. The semiconductor device of claim 12, wherein an upper surface of the strained fin is co-planar with an upper surface of the relaxed fin.

18. The semiconductor device of claim 12, wherein in the strained fin and the relaxed fin are formed to a height greater than a critical thickness that which growth defects occur in an epitaxially formed Si blanket layer or in an epitaxially formed Ge blanket layer.

19. A design structure embodied in a machine readable storage medium for designing, manufacturing, or testing an integrated circuit, the design structure comprising:
a semiconductor substrate comprising a buried dielectric layer on a base substrate, wherein the buried dielectric layer is composed of an oxide, nitride, or oxynitride;
a relaxed fin directly upon the buried dielectric layer, the relaxed fin comprising a relaxed material having a relaxed crystalline lattice, and;
a strained fin directly upon the buried dielectric layer, the strained fin comprising a strained material of increased crystalline lattice distortion relative to the relaxed material,
wherein the relaxed material is SiGe having a first atomic Ge concentration, and the strained material is SiGe having a second atomic Ge concentration greater than the first Ge concentration.

20. (canceled)

21. The design structure of claim 19, wherein:
the first atomic Ge concentration is between 20% and 40%; and
the second atomic Ge concentration is at least 50%.

22. The design structure of claim 21, wherein an upper surface of the strained fin is co-planar with an upper surface of the relaxed fin.

23. The design structure of claim 22, wherein in the strained fin and the relaxed fin are formed to a height greater than a critical thickness that which growth defects occur in an epitaxially formed Si blanket layer or in an epitaxially formed Ge blanket layer.

24. The design structure of claim 22, wherein the critical thickness is 10 nm.

25. The design structure of claim 22, wherein the strained fin and the relaxed fin each has a height in a range of 40 nm to 60 nm and a width in a range of 3 nm to 12 nm.

26. The semiconductor device of claim 18, wherein the critical thickness is 10 nm.

27. The semiconductor device of claim 12, wherein the strained fin and the relaxed fin each has a height in a range of 40 nm to 60 nm and a width in a range of 3 nm to 12 nm.

28. The semiconductor device of claim 27, wherein:
the first atomic Ge concentration is between 20% and 40%; and
the second atomic Ge concentration is at least 50%.
